(19) United States
(12) Patent Application Publication
(10) Pub. No.: US 2017/0373249 A1
(43) Pub. Date: Dec. 28, 2017

(54) ONE-POT ORGANIC POLYMERIC SURFACE ACTIVATION AND NANOPARTICLE REDUCTION

(71) Applicants: Ganesh KANNAN, Sugar lands, TX (US); Ihab ODEH, Sugar Land, TX (US); Nitin CHOPRA, Sugar Land, TX (US); SABIC Global Technologies B.V., Bergen op Zoom (NL)

(72) Inventors: Ganesh Kannan, Sugar Land, TX (US); Ihab Odeh, Sugar Land, TX (US); Nitin Chopra, Sugar Land, TX (US)

(21) Appl. No.: 15/536,034

(22) PCT Filed: Jan. 8, 2016
(86) PCT No.: PCT/US2016/012563

§ 371 Date: Jun. 14, 2017

Related U.S. Application Data
(60) Provisional application No. 62/104,126, filed on Jan. 16, 2015.
(60) Provisional application No. 62/275,835, filed on Jan. 7, 2016.

(51) Int. Cl. H01L 51/00; C01B 32/198; H01L 33/40; H01L 51/44

(52) U.S. Cl. CPC H01L 51/0002; H01L 51/0045; H01L 51/442; C01B 32/198; H01L 51/004; H01L 33/40; H01L 2251/303

(57) ABSTRACT

Methods for attaching a reducible nanomaterial to an organic polymer are described herein. A method includes subjecting a reaction mixture that includes the reducible nanomaterial and the organic polymer to a reducing agent under reaction conditions sufficient to reduce the nanomaterial, activate the organic polymer, and attach the reduced nanomaterial to the organic polymer during the reaction.

### CROSS REFERENCE TO RELATED APPLICATIONS

This application claims benefit to U.S. Provisional Patent Application No. 62/104,126 titled “ONE-POT ORGANIC POLYMERIC SURFACE ACTIVATION AND NANOPARTICLE REDUCTION”, filed Jan. 16, 2015 and U.S. Provisional Patent Application No. 62/275,835 titled “ONE-POT ORGANIC POLYMERIC SURFACE ACTIVATION AND NANOPARTICLE REDUCTION”, filed Jan. 7, 2016. The contents of both referenced applications are incorporated herein by reference.

### BACKGROUND OF THE INVENTION

### A. Field of the Invention

The invention generally concerns a process for making materials that can be used in a wide-array of applications and electronic devices. In particular, the invention concerns a one-pot synthesis process for attaching a reducible nanomaterial (e.g., graphene oxide) to an organic polymer (e.g., polypropylene, polyethylene terephthalate, etc.) in the presence of a reducing agent (e.g., amine containing reducing agents).

### B. Description of Related Art

Nanomaterials have become attractive materials because of their properties of large specific surface area, number of surface atoms, surface energy and surface tension and small size effect, surface effect, quantum scale effect and macroscopic quantum tunnel effect, etc. Thus, nanomaterials have wide application in photology, non-linear photology, electrology, magnetology, energy fields, and chemistry fields. Examples of nanomaterials include graphene, graphene oxide, reduced graphene oxide, metal particles, metal oxides and the like.

Many nanomaterials can be fixed in a polymer based material, attached to the surface of a polymeric substrate, or dispersed and/or aligned in a polymer based material. Current methods for preparing such materials require multiple steps. By way of example, nanomaterials can be deposited on polymers using transfer processes, roll-to roll processes, chemical vapor deposition or physical vapor deposition. One problem associated with depositing nanomaterials on the surface of polymeric materials is that the nanomaterials do not sufficiently adhere or attach to the polymers. The attachment issues are currently addressed by using multiple processing steps, where a first step is to activate the polymer or polymeric surface with a functional group. Subsequently, a second step introduces a nanomaterial to the functionalized polymer to create the desired attachment. Each of the functionalizing and attachment steps require their own set of reaction conditions and processing materials, thereby adding to the complexity and costs associated with attaching nanomaterials to polymeric materials. Current methods to disperse and align graphene fillers in polymers include sonication, solution or melt mixing, in-situ mechanical exfoliation, in-situ polymerization, and physical impregnation. To obtain alignment or film-type of dispersion of graphene, within polymers, electric and/or magnetic field have to be applied to the composites. This can also lead to heating of components and requires additional processing steps to obtain a robust interface between the polymer and graphene. Apart from these challenges, some composite fabrication methods involve tedious and multi-step covalent functionalization of graphene.

### SUMMARY OF THE INVENTION

A solution to the problems associated with attaching nanomaterials to polymeric substrates has been discovered and/or dispersing nanomaterials in a polymeric substrate (e.g., a polymeric matrix). The solution resides in the ability to (1) reduce a reducible nanomaterial, (2) activate an organic polymer, and (3) attach the reduced nanomaterial to the activated organic polymer under a “one-pot” synthesis scheme in which steps (1)-(3) can be performed in the same reactor under the same processing conditions. Such a one-pot process leads to in situ activation of the reducible moiety of the nanomaterial (for example, oxygen moieties) which can bind the nanomaterial to the activated moiety (for example, a carbon or heteroatom) of the polymer surface. Without wishing to be bound by theory, it is believed that the reduction and activation reactions can occur simultaneously or substantially simultaneously when a reducing agent is added to a mixture of the reducible nanomaterial and the organic polymer. By way of example, a polymeric material (e.g., an organic polymer), a reducible nanomaterial (e.g., graphene oxide), and a reducing agent (e.g., an amine containing reducing agent—e.g., hydrazine) can be used in a one-pot reaction synthesis under a given set of reaction conditions (e.g., aqueous conditions at 75 to 85° C.) to simultaneously or substantially simultaneously reduce the graphene oxide, activate the organic polymer, and attach the reduced graphene oxide to the activated organic polymer. The resulting material can be used in a wide array of applications, non-limiting examples of which include energy devices, pollution control devices, gas separation devices, electrodes, interconnects in flexible electronic devices, etc.

In one aspect of the present invention, there is disclosed a method for attaching a reducible nanomaterial to an organic polymer. The method includes subjecting a reaction mixture that includes the reducible nanomaterial and the organic polymer to a reducing agent under reaction conditions sufficient to reduce the nanomaterial, activate the organic polymer, and attach the reduced nanomaterial to the organic polymer during the reaction. In some aspects of the invention, the reaction conditions are sufficient to simultaneously or substantially simultaneously reduce the nanomaterial, activate the organic polymer and attach the reduced nanomaterial to the surface of the organic polymer. The reduced nanomaterial can be covalently bonded to the surface of the organic polymer after the reduction and activation reactions. In other instances, the reduced material can be attached to the organic polymer via hydrogen bonds. In still further instances, a combination of covalent bonds and hydrogen bonds can attach the reduced material to the organic polymer. In a particular aspect, the reaction mixture can be obtained by depositing the reducible nanomaterial on the organic polymer. In a preferred aspect, the reducible material is deposited on the surface of the organic polymer. The reaction mixture can be treated with the reducing agent after or during deposition of the reducible nanomaterial on the organic polymer. The reducible nanomaterial can be any nanomaterial that includes one or more atoms or metals that can be reduced or removed such that the oxidation state of the nanomaterial is lowered. In a particular aspect of the invention, the nanomaterial has not previously been reduced and/or the organic polymer has not previously been activated. In some instances, the reducible material can include additional nanostructures (for example, nanorods, nanowires, nanoparticles, quantum dots, or any combination thereof). The nanostructures can be on the surface of the reducible nanomaterial. In a particular instance, graphene oxide is decorated with the additional nanostructures. The additional nanostructures can include metal oxide, metal, bi-metallic compounds, tri-metallic compounds, metal alloys, carbon-based compounds, carbides, chalcogenides, or any combination thereof. In one embodiment, the organic polymer is in the form of an organic polymer substrate such as a film, sheet, or fiber mesh, and the reduced nanomaterial is attached to the surface of the polymeric substrate after the reaction. A non-limiting example of a reducible nanomaterial includes an oxygen-containing carbon nanostructure, a defect-containing carbon nanotube, a transition metal compound, or a transition metal oxide. In a preferred aspect, the oxygen-containing carbon nanostructure is graphene oxide. In some aspects, the transition metal compound or transition metal oxide nanomaterial includes vanadium. The organic polymer can be any organic polymer. In a preferred aspect, the organic polymer is a thermoplastic polymer or a blend of thermoplastic polymers. Thermoplastic polymers include polyethylene terephthalate (PET), a polycarbonate (PC) family of polymers, polybutylene terephthalate (PBT), poly(1,4-cyclohexylidene cyclohexane-1,4-dicarboxylate) (PCCD), glycol modified polycyclohexyl terephthalate (PCTG), poly(phenylene oxide) (PPO), polypropylene (PP), polyethylene (PE), polyvinyl chloride (PVC), polystyrene (PS), polymethyl methacrylate (PMMA), polyethyleneimine (PEI) and its derivatives, polyetherimide and its derivatives, thermoplastic elastomer (TPE), terephthalic acid (TPA) elastomers, poly(cyclohexanedimethylene terephthalate) (PCT), polyethylene naphthalate (PEN), polyamide (PA), polystyrene sulfonate (PSS), sulfonated polysulfone family of polymers, polyether ether ketone (PEEK), or combinations or blends thereof. In some embodiments, the organic polymer is polypropylene, polyethylene terephthalate, polyetherimide, or polyethylene, or blends thereof. In certain embodiments, the organic polymer is polypropylene or polyethylene terephthalate. In some aspects, the polypropylene polymer is biaxially oriented polypropylene. The reducing agent can be any substance capable of reducing the functional groups of the nanomaterial and activating the organic polymer. In a preferred aspect, the reducing agent is a nitrogen containing compound. Nitrogen containing compounds include mono-amines, di-amines, polyamines, hydrazines, hydrazine monohydrate, di-imides, or mixtures thereof. In a preferred embodiment, the reducing agent is hydrazine monohydrate. In a particular embodiment, the reaction mixture includes graphene oxide and an organic polymer, and the reducing agent is hydrazine monohydrate. In embodiments, when the polymer is biaxially oriented polypropylene (BOPP), the BOPP is flame or corona plasma treated. Suitable reaction conditions include temperatures from 25 to 500° C., 50 to 250° C., or 75 to 100° C. at pressures of 1 atmosphere. In particular instances, when flame treatment is used, the conditions can include the use of a mixture of air at 138-345 kPA and a fuel (e.g., gas such as butane, propane, methane, coal gas, etc.) at lower pressure such as less than 10 kPa, less than 5 kPa, or from 1 to 3 kPa. For corona plasma treatment, non-limiting corona energy levels (kJ/m²) of at least 5, 10, 20, 50, 70, 100 or more can be used or a range of 5 to 100 kJ/m² can be used. Air-corona or corona treatment under a chemical atmosphere can be used. In some aspects the reaction mixture is subject to plasma discharge under a reducing agent atmosphere, for example, a hydrazine, atmosphere.

In another aspect of the invention, a polymeric material having reduced graphene oxide attached to the surface of the material is described. The polymeric material is prepared by the processes described throughout the specification. The polymeric material can be used in optoelectronics, catalysis, batteries, super capacitors, ultrasensitive sensors for pressure changes, gas storage or gas separation, lubricants, energy storage devices, a coating (e.g., optical fiber protection coatings, functional coatings, masks for printed electronics), lightening protection system, smart textile, sensors, high-strength structural material, light-weight structural material and the like. In a particular aspect, the polymeric material is conductive. The polymeric material can be included in an electronic device, a printed circuit board, or an integrated circuit. The electronic device can be a transistor, a resistor, a logic device, a sensor, an antenna, an integrated circuit, an electroluminescence device or a field effect device. In some embodiments, the electronic device is an optoelectronic device. The optoelectronic device can be a touch panel, a liquid crystal display, a solar cell, a sensor, a memory element, an antenna, or a light emitting diode. In some embodiments, the polymeric material is an electrode such as a transparent electrode, flexible electrode, or a transparent flexible electrode. The electrode can be used as an anode, a cathode or both in a photovoltaic device, or an energy storage device. In some embodiments, the polymeric material is used as a transparent top electrode in a photovoltaic device and an opaque or reflective material is used as a bottom electrode in the photovoltaic device. The electrode of the present invention can also be used as circuitry in flexible electronic circuits. In other aspects of the invention, the polymeric material of the present invention can be used at a pollution control and mitigation platform by catalyzing the destruction of undesired gases such as SOx and NOx. In some aspects of the invention, the polymeric material is used in a gas separation surface where two gases can be separated based on differential absorption rate to the surface. In some embodiments, the polymeric material is included in a polymeric laminate (sheet or film) that includes the polymeric material and an additional polymeric material, where the reduced nanomaterial is between the polymer of the polymeric material and the additional polymeric material.

In the context of the present invention 50 embodiments are described. Embodiment 1 describes a method for attaching a reducible nanomaterial to an organic polymer. The method can include subjecting a reaction mixture that includes the reducible nanomaterial and the organic polymer to a reducing agent under reaction conditions sufficient to reduce the nanomaterial, activate the organic polymer, and attach the reduced nanomaterial to the organic polymer during the reaction. Embodiment 2 is the method of embodiment 1, further including obtaining the reaction mixture by depositing the reducible nanomaterial on the organic polymer. Embodiment 3 is the method of embodiment 2, wherein the reaction mixture is treated with the reducing agent after the reducible nanomaterial has been deposited on the organic polymer. Embodiment 4 is the method of embodiment 2, wherein the reaction mixture is treated with the reducing agent during deposition of the reducible nanomaterial on the organic polymer. Embodiment 5 is the method of any one of embodiments 1 to 4, wherein the reducible nanomaterial is an oxygen-containing carbon nanostructure, a defect-containing carbon nanotube, a transition metal compound, or a transition metal oxide. Embodiment 6 is the method of embodiment 5, wherein the reducible material includes additional nanostructures. Embodiment 7 is the method of embodiment 6, wherein the additional nanostructures are nanorods, nanowires, nanoparticles, quantum dots, or any combination thereof. Embodiment 8 is the method of any one of embodiments 7 to 8, wherein the nanostructures include a metal oxide, a metal, a bi-metallic compound, a tri-metallic compound, an alloy, a carbon-based compound, a carbide, a chalcogenide, or any combination thereof. Embodiment 9 is the method of any one of embodiments 5 to 8, wherein the oxygen-containing carbon nanostructure is graphene oxide. Embodiment 10 is the method of embodiment 5, wherein the transition metal compound or the transition metal oxide includes vanadium. Embodiment 11 is the method of any one of embodiments 1 to 10, wherein the organic polymer is a thermoplastic polymer or blend thereof. Embodiment 12 is the method of embodiment 11, wherein the thermoplastic polymer is polyethylene terephthalate (PET), a polycarbonate (PC) family of polymers, polybutylene terephthalate (PBT), poly(1,4-cyclohexylidene cyclohexane-1,4-dicarboxylate) (PCCD), glycol modified polycyclohexyl terephthalate (PCTG), poly(phenylene oxide) (PPO), polypropylene (PP), polyethylene (PE), polyvinyl chloride (PVC), polystyrene (PS), polymethyl methacrylate (PMMA), polyethyleneimine or polyetherimide (PEI) and their derivatives, thermoplastic elastomer (TPE), terephthalic acid (TPA) elastomers, poly(cyclohexanedimethylene terephthalate) (PCT), polyethylene naphthalate (PEN), polyamide (PA), polysulfone sulfonate (PSS), sulfonates of polysulfones, polyether ether ketone (PEEK) or combinations or blends thereof. Embodiment 13 is the method of embodiment 12, wherein the thermoplastic polymer is polypropylene, polyethylene terephthalate, polyethyleneimine, polyetherimide, or polyethylene, or blends thereof. Embodiment 14 is the method of embodiment 13, wherein the organic polymer is polypropylene or polyethylene terephthalate. Embodiment 15 is the method of embodiment 14, wherein the polypropylene is biaxially oriented polypropylene. Embodiment 16 is the method of embodiment 15, wherein the biaxially oriented polypropylene is flame or Corona treated. Embodiment 17 is the method of any one of embodiments 1 to 16, wherein the reducing agent is a nitrogen containing compound. Embodiment 18 is the method of embodiment 17, wherein the reducing agent is a mono-amine, a di-amine, a polyamine, a hydrazine, a hydrazine monohydrate, a di-imide, or mixtures thereof. Embodiment 19 is the method of embodiment 18, wherein the reducing agent is a hydrazine monohydrate. Embodiment 20 is the method of any one of embodiments 1 to 19, wherein the nanomaterial has not previously been reduced. Embodiment 21 is the method of any one of embodiments 1 to 20, wherein the polymer has not previously been activated. Embodiment 22 is the method of any one of embodiments 1 to 22, wherein the organic polymer is in the form of an organic polymeric substrate and the reduced nanomaterial is attached to the surface of the substrate after the reaction. Embodiment 23 is the method of embodiment 22, wherein the substrate is in the form of a film, sheet, or a fiber mesh. Embodiment 24 is the method of any one of embodiments 1 to 23, wherein the reduced nanomaterial is covalently attached to the organic polymer after the reaction. Embodiment 25 is the method of any one of embodiments 1 to 23, wherein the reduced material is attached to the organic polymer via hydrogen bonds or via a combination of hydrogen bonds and covalent bonds. Embodiment 26 is the method of any one of embodiments 1 to 25, wherein the reaction conditions include a temperature from 25 to 500° C. Embodiment 27 is the method of any one of embodiments 1 to 26, wherein the reaction mixture is an aqueous mixture.

Embodiment 28 is a polymeric material having reduced graphene oxide attached to the surface of an organic polymer, wherein the polymeric material is prepared by the process of any one of embodiments 1 to 27. Embodiment 29 is the polymeric material of embodiment 28, wherein the polymeric material is included in an electronic device. Embodiment 30 is the polymeric material of embodiment 28, wherein the electronic device is a transistor, a resistor, a logic device, a sensor, an antenna, an integrated circuit, an electroluminescence device, a field effect device, or lightening protection system. Embodiment 31 is the polymeric material of embodiment 30, wherein the electronic device is an optoelectronic device. Embodiment 32 is the polymeric material of embodiment 30, wherein the optoelectronic device is a touch panel, a liquid crystal display, a solar cell, a sensor, a memory element, an antenna, or a light emitting diode. Embodiment 33 is the polymeric material of embodiment 28, wherein the polymeric material is an electrode. Embodiment 34 is the polymeric material of embodiment 33, wherein the electrode is used as an anode or cathode in an energy storage device. Embodiment 35 is the polymeric material of embodiment 34, wherein the energy storage device is a capacitor. Embodiment 36 is the polymeric material of embodiment 32, wherein the electrode is a transparent electrode. Embodiment 37 is the polymeric material of embodiment 36, wherein the transparent electrode is used as an anode, a cathode, or both in a photovoltaic device or an energy storage device. Embodiment 38 is the polymeric material of embodiment 37, wherein the transparent electrode is used as the top electrode in the photovoltaic device, wherein the bottom electrode is opaque or reflective. Embodiment 39 is the polymeric material of embodiment 38, wherein the electrode is an opaque electrode. Embodiment 40 is the polymeric material of any one of embodiments 32 to 39, wherein the electrode is a flexible electrode. Embodiment 41 is the polymeric material of embodiment 39, wherein the electrode is used as circuitry in flexible electronic circuits. Embodiment 42 is the polymeric material of embodiment 24, wherein the polymeric material is included in a printed circuit board or an integrated circuit. Embodiment 43 is the polymeric material of embodiment 28, wherein the polymeric material is used as a catalyst for destruction of SOₓ or NOₓ gases. Embodiment 44 is the polymeric material of embodiment 42, wherein the catalyst is used at a pollution control and mitigating platform. Embodiment 45 is the polymeric material of embodiment 28, wherein the polymeric material is used as to separate two gases from each other. Embodiment 46 is the polymeric material of embodiment 45, wherein the separation takes place on the surface of the polymeric material, and wherein the separation is based on differential absorption rate to the surface. Embodiment 47 is the polymeric material of embodiment 28, wherein the polymeric material is included in a coating, light protection system, a smart textile, high-strength material, and light-weight structural material. Embodiment 48 is the polymer material of embodiment 47, wherein the coating is an optical fiber coating, a mask, or a functional coating. Embodiment 49 is the polymeric material of any one of embodiments 28 to 48, wherein the polymeric material is conductive. Embodiment 50 is the polymeric material of any one of embodiments 28 to 49, wherein the polymeric material is included in a polymeric sheet or film that includes the polymeric material and an additional polymeric, wherein the reduced nanomaterial is between the polymer of the polymeric material and the additional polymeric.

The following includes definitions of various terms and phrases used throughout this specification.

“Attach” or “attached” refers to the attachment or adhesion between the nanomaterial and the polymer or polymeric surface of a material. In certain aspects, and after employing the process of the present invention, the nanomaterial can be covalently bonded to the surface of the polymer or can be bonded through hydrogen bonds or a combination of covalent and hydrogen bonds.

“Activated” when used to modify the terms or phrases “polymer”, “organic polymer,” or “polymeric surface” means that the polymer, organic polymer, or polymeric surface has been functionalized with a functional group, oxidized, or reduced, or any combination thereof, to aid in the attachment of a nanomaterial to said polymer. Therefore, a polymer that has not previously been activated prior to using a process of the present invention is a polymer or organic polymer or polymeric material that has not previously been subjected to a functionalization, oxidation, or reduction reaction that would aid in the attachment of a nanomaterial to said polymer.

“Nanomaterial” refers to an object or material in which at least one dimension of the object or material is equal to or less than 1000 nm (e.g., one dimension is 1 to 1000 nm in size). In a particular aspect, the nanomaterial includes at least two dimensions that are equal to or less than 1000 nm (e.g., a first dimension is 1 to 1000 nm in size and a second dimension is 1 to 1000 nm in size). In another aspect, the nanomaterial includes three dimensions that are equal to or less than 1000 nm (e.g., a first dimension is 1 to 1000 nm in size, a second dimension is 1 to 1000 nm in size, and a third dimension is 1 to 1000 nm in size). The shape of the nanomaterial can be of a wire, a particle, a sphere, a rod, a tetrapod, a hyper-branched structure, a tube, multiple tubes, or mixtures thereof.

“Reduction” refers to a decrease in the oxidation state of an element of the Periodic Table.

“Reducing agent” refers to any compound that can donate electrons or hydrogen to another compound. Non-limiting examples of reducing agents include amines and di-amines such as hydrazine.

“Reducible nanomaterial” refers to a nanomaterial that has the capacity to gain electrons or hydrogen.

“Oxidation” refers to an increase in the oxidation state of an element of the Periodic Table.

“Substrate” refers to a material onto which the nanomaterial or polymeric material is attached. In certain instances, the substrate can be a polymeric material. The substrate can be rigid or flexible. The substrate can be transparent, translucent, or opaque, or any degree of transparency, translucency, or opacity as desired. Non-limiting examples of rigid substrates include, for example, glass, polycarbonates, acrylics, etc. Non-limiting examples of flexible substrates include polyesters (e.g., polyethylene terephthalate, polyester naphthalate, and polycarbonate), polyolefins (e.g., linear, branched, and cyclic polyolefins), polyvinyls (e.g., polyvinyl chloride, polyvinylidene chloride, polyvinyl acetals, polystyrene, polyacrylates, etc.), cellulose ester bases (e.g., cellulose triacetate, cellulose acetate), polysulfones such as polyethersulfone, polyimides, silicones and other conventional polymeric films. Additional examples of suitable substrates can be found in, e.g., U.S. Pat. No. 6,975,067, which are incorporated herein by reference.

The term “about” or “approximately” are defined as being close to as understood by one of ordinary skill in the art, and in one non-limiting embodiment the terms are defined to be within 10%, preferably within 5%, more preferably within 1%, and most preferably within 0.5%.

The term “substantially” and its variations are defined as being largely but not necessarily wholly what is specified as understood by one of ordinary skill in the art, and in one non-limiting embodiment substantially refers to ranges or time periods within 10%, within 5%, within 1%, or within 0.5% of a referenced range or time period.

The terms “inhibiting” or “reducing” or “preventing” or “avoiding” or any variation of these terms, when used in the claims and/or the specification includes any measurable decrease or complete inhibition to achieve a desired result.

The term “effective,” as that term is used in the specification and/or claims, means adequate to accomplish a desired, expected, or intended result.

The use of the word “a” or “an” when used in conjunction with the term “comprising” in the claims or the specification may mean “one,” but it is also consistent with the meaning of “one or more,” “at least one,” and “one or more than one.”

The words “comprising” (and any form of comprising, such as “comprise” and “comprises”), “having” (and any form of having, such as “have” and “has”), “including” (and any form of including, such as “includes” and “include”) or “containing” (and any form of containing, such as “contains” and “contain”) are inclusive or open-ended and do not exclude additional, unrecited elements or method steps.

The methods for making polymeric materials of the present invention can “comprise,” “consist essentially of,” or “consist of” particular ingredients, components, compositions, etc. disclosed throughout the specification. With respect to the transitional phase “consisting essentially of,” in one non-limiting aspect, a basic and novel characteristic of the process of the present invention is the ability to reduce a reducible nanomaterial and activate an organic polymer in “one-pot” such that the reduced nanomaterial attaches to the organic polymer.

Other objects, features and advantages of the present invention will become apparent from the following figures, detailed description, and examples. It should be understood, however, that the figures, detailed description, and examples, while indicating specific embodiments of the invention, are given by way of illustration only and are not meant to be limiting. Additionally, it is contemplated that changes and modifications within the spirit and scope of the invention will become apparent to those skilled in the art from this detailed description. In further embodiments, features from specific embodiments may be combined with features from other embodiments. For example, features from one embodiment may be combined with features from any of the other embodiments. In further embodiments, additional features may be added to the specific embodiments described herein.

### BRIEF DESCRIPTION OF THE DRAWINGS

FIG. 1 is a non-limiting chemical structure of a graphene oxide compound.

FIG. 2 is a schematic of an embodiment of a method to produce the polymeric material of the present invention.

FIG. 3 is a non-limiting chemical structure of a reduced graphene oxide compound attached to an organic polymer.

FIG. 4 is a schematic of an embodiment of a method to produce the polymeric material of the present invention.

FIGS. 5A and 5B depict a schematic of an embodiment of a method to prepare the polymeric material that includes reducible material decorated with the nanostructures.

FIG. 6 depicts a schematic of a roll-to roll process to make a flexible laminate that includes the polymeric material of the present invention.

FIG. 6A is an enlarged top view of the flexible laminate of FIG. 6.

FIG. 7A shows an FTIR spectrum for a PET blank.

FIG. 7B shows an FTIR spectrum for a PET substrate coated with reduced graphene oxide made using the method of the present invention.

FIG. 8A shows the FTIR spectra for graphene oxide dispersed on PET.

FIG. 8B shows the comparison of the carbonyl stretch region for FIG. 8A and FIG. 7B.

FIG. 9A is an enlarged region of the carbonyl stretch region from around 1725 cm⁻¹ of the FIG. 8B FTIR spectra.

FIG. 9B is an enlargement of the carbonyl stretch region around 1620 cm⁻¹ of the FIG. 8B FTIR spectra.

FIGS. 10A and 10B are blank PET substrate (10A: transmission mode optical image; 10B: reflection mode optical image).

FIGS. 11A and 11B are PET substrate uniformly coated with graphene nanoplatelets (11A: transmission mode optical image; 11B: reflection mode optical image).

FIG. 12A is an image of a sample with reduced graphene oxide integrated between two PET substrates of the present invention that shows increased peel resistance between the substrates.

FIG. 12B is an image of a sample with graphene oxide between two PET substrates, where no reducing treatment was performed. This sample shows negligible peel resistance, where the two substrates separate easily from one another compared to samples shown in FIG. 12A.

FIGS. 13A and 13B are scanning electron microscope (SEM) images of PET uniformly coated with reduced graphene oxide (or graphene) nanoplatelets at a 20 μm and 4 μm scale respectively.

While the invention is susceptible to various modifications and alternative forms, specific embodiments thereof are shown by way of example in the drawings and may herein be described in detail. The drawings may not be to scale.

### DETAILED DESCRIPTION OF THE INVENTION

The use of nanomaterials attached to polymers or polymeric surfaces has far-reaching implications in today's society. Some non-limiting uses of such composite materials include energy devices, pollution control devices, gas separation devices, electrodes, interconnects in flexible electronic devices, etc.

As discussed above, the previous processes used to make such materials can be complicated and inefficient. For instance, such processes typically require at least two separate steps that require their own reaction conditions. The first step is typically activation of the polymer or polymeric surface with a functional group. The second step introduces a nanomaterial to the functionalized polymer to create the desired attachment.

By comparison, the one-pot synthesis processes of the present invention provide distinct advantages when compared to the aforementioned multi-step processes. In the one-pot processes, a mixture of a reducible nanomaterial and an organic polymer can be contacted with a reducing agent. The reducing agent is capable of reducing the nanomaterial and activating the organic polymer such that the reduced nanomaterial attaches to the surface of the organic polymer, while preserving the properties of the reduced nanomaterial. Without wishing to be bound by theory, it is believed that the reduction and activation reactions can occur simultaneously or substantially simultaneously. Notably, it allows reduction of nanomaterials (for example, graphene oxide (GO) to reduced graphene oxide (rGO)) and produces activated moieties on the polymer site that can bond to the reduced nanomaterial in situ.

These and other non-limiting aspects of the present invention are discussed in further detail in the following sections with reference to the Figures.

### A. Materials

1. Reducible Nanomaterials

Reducible nanomaterials are nanomaterials that have the capacity to gain electrons or hydrogen. Non-limiting examples of such materials include oxygen-carbon nanostructures, defect-containing carbon nanotube structures, transition metals compounds, metal oxides, or combinations thereof.

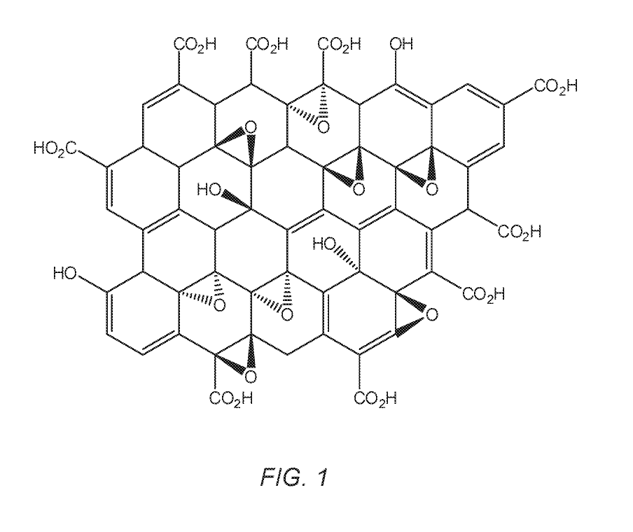

A non-limiting oxygen-carbon nanostructure includes graphene oxide. Graphene oxide can be prepared by treating graphite using the Hummer or Hummer modified processes (see Chen et. al., “An improved Hummers method for eco-friendly synthesis of graphene oxide”, Carbon, vol. 64, pp. 225-229 (2013), which is incorporated into the present application by reference). Graphene oxide includes many forms of oxidized or substituted carbon, for example, carbonyls, epoxides, alcohols, and carboxylic acids. The actual chemical composition of oxidized graphene varies due to the processing conditions to obtain. A non-limiting structure of graphene oxide is shown as FIG. 1. Other structures are contemplated with various alcohol, carbonyls, carboxylic acids and epoxides are contemplated. Graphene oxide is commercially available from many sources. The graphene oxide can be combined with a solvent (e.g., water or non-reactive solvent). A non-limiting example of a graphene oxide solution is an aqueous solution of graphene oxide colloids. A non-limiting example of a source of graphene oxide is Sigma-Aldrich® (Milwaukee, Wis., USA) or Graphenea (San Sebastian, SPAIN).

Defect-containing carbon nanotube structures include single cylindrical wall and multi-walled nanotubes that contain atomic vacancies or a rearrangement of the carbon bonds. A rearrangement of the carbon bonds can be referred to as a Stone-Wales (SW) defect. Defect-containing carbon nanotube structures can have larger absorption energies and charge transfer energies than those of pristine carbon nanotubes. Non-limiting examples of defects include vacancy in the lattice (mono- or di-vacancy), result of a knock-on damage, originated by chemisorbant or physiosorbent adduct, or defects that are caused by mechanical processes (see P. G. Collins, Defects and Disorder in Carbon Nanotubes, University of California at Irvine, Irvine, USA; see also P. G. Collins, Defects and Disorder in Carbon Nanotubes in Oxford Handbook of Nanoscience and Technology: Frontiers and Advances, Narlikar, A. V. & Fu, Y. Y.Eds. (Oxford Univ. Press, Oxford, 2009), both of which are incorporated by reference). Defects in carbon nanotubes are typically characterized by a combination of electrochemical (such as conductance), spectroscopic (such as Raman), and microscopic (such as scanning tunneling microscopy, optical light microscopy and transmission electron microscopy) techniques (P. G. Collins (2009)). Commercial sources of such carbon nanotubes include Nanocyl SA (Sambreville, Belgium), Cnano Technology Limited (San Francisco, Calif., USA), and Hyperion Catalysis International Inc. (Cambridge, Mass., USA).

Transition metals compounds and transition metal oxides include compounds containing metals from Groups IIIB, IVB, VB, VIB, VIIIB, VIII, IB and IIB (Columns 3-12) of the Periodic Table, preferably metals from Group V (Column 5), most preferably, vanadium. Non-limiting examples of metal oxides include vanadium pentoxide (V₂O₅), ammonium metavanadate (NH₄VO₃), molybdenum trioxide, ammonium molybdate (VI), tungsten trioxide, ammonium tungstate. Transition metal compounds or transition metal oxides are available from commercial sources. A non-limiting example of a source of transition metal compounds or transition metal oxides is Sigma-Aldrich® (Milwaukee, Wis., USA).

The reducible material can include nanostructures deposited on the surface of the reducible material. The nanostructures can be any shape or size (e.g., nanowires, nanoparticles, nanorods, or quantum dots). A non-limiting example is graphene oxide decorated on one or both surfaces with nanoparticles. In some embodiments, the reducible material can be decorated with nanostructures. Such nanostructures can include metal oxide, metal, bi-metallic compounds, tri-metallic compounds, metal alloys, carbon-based compounds, carbides, chalcogenides, or any combination thereof. Non-limiting examples of additional nanostructures include ZnO nanoparticles, Au nanorods, Pt nanoparticles, and CdSe/ZnS core/shell quantum dots. Nanostructures are commercially available from commercial sources. Non-limiting examples of sources of nanostructures are Sigma-Aldrich® (Milwaukee, Wis., USA) and Nanosys® (Milpitas, Calif., USA).

2. Organic Polymers

The organic polymer can be any organic polymer, copolymer, terpolymer, cross-linked polymers, or a polymer blend comprising a polymer, copolymer, terpolymer, cross-linked polymers, or combinations thereof. In a particular aspect, the polymers have not gone any treatments to functionalize, oxidize, or reduce the carbon, oxygen, or nitrogen moieties in the polymers. In a preferred aspect, the organic polymers are a thermoplastic polymer or a blend of thermoplastic polymers. Thermoplastic polymers include polyethylene terephthalate (PET), a polycarbonate (PC) family of polymers, polybutylene terephthalate (PBT), poly(1,4-cyclohexylidene cyclohexane-1,4-dicarboxylate) (PCCD), glycol modified polycyclohexyl terephthalate (PCTG), poly(phenylene oxide) (PPO), polypropylene (PP), polyethylene (PE), polyvinyl chloride (PVC), polystyrene (PS), polymethyl methacrylate (PMMA), polyethyleneimine (PEI) and its derivatives, polyetherimide and its derivatives, thermoplastic elastomer (TPE), terephthalic acid (TPA) elastomers, poly(cyclohexanedimethylene terephthalate) (PCT), polyethylene naphthalate (PEN), polyamide (PA), polystyrene sulfonate (PSS), sulfonated polysulfone family of polymers, polyether ether ketone (PEEK), or combinations or blends thereof. In some embodiments, the organic polymer is polypropylene, polyethylene terephthalate, polyethyleneimine, or polyethylene, or blends thereof. In certain embodiments, the organic polymer is polypropylene or polyethylene terephthalate. In some aspects, the polypropylene polymer is biaxially oriented polypropylene (BOPP). In some embodiments, the polymer can be a polymeric substrate in which its surface is patterned. The nanomaterial can then be attached to the pattern in the surface area via the processes of the present invention. The polymer can be functionalized with functional groups either in the polymer back bone or pendant such as esters, carbonates, amides, etherimides, acids, hydroxyl, etc. that can react with amine such as amino silanes, hydrazine, halogenated amines, etc. The polymers that do not have such chemistry can be pre-conditioned. For example, such as flame-treated polyolefins (e.g., polyethylene).

3. Reducing Agents

The reducing agent can be any substance capable of reducing the functional groups of the nanomaterial and activating the organic polymer. In a preferred aspect, the reducing agent is a nitrogen containing compound. Nitrogen containing compounds include mono-amines, di-amines, polyamines, hydrazines, hydrazine monohydrate, di-imides, or mixtures thereof. In a preferred embodiment, the reducing agent is hydrazine monohydrate. Mono-amines include compounds having one nitrogen atom, for example, primary amines and secondary amines, with primary amines being preferred. Non-limiting examples of mono-amines include alkyl amines, ethylamine, propylamine, 2-(N,N-dimethylamino)ethyl methacrylate (DMAEMA), aralkyl amines, benzyl amine, aromatic amines, aniline, naphthylamine. toluidines, N,N-dimethyl-p-toluidine. Diamines include compounds that have two (2) nitrogen atoms. Examples of diamines include alkyl amines, ethylenediamine, aryl amines, phenyl diamine, and hydrazines. Examples of hydrazine compounds include hydrazine monohydrate. Amines and diamines are commercially available from numerous suppliers. A non-limiting example of a commercial supplier is Sigma-Aldrich® (Milwaukee, Wis., USA).

### B. Methods For Making Polymeric Material

In some embodiments, attaching a reducible nanomaterial to an organic polymer includes subjecting a reaction mixture that includes the reducible nanomaterial and the organic polymer to a reducing agent under reaction conditions sufficient to reduce the nanomaterial, activate the organic polymer, and attach the reduced nanomaterial to the organic polymer during the reaction. An organic polymer can be obtained and mixed with the reducible nanomaterial in a suitable solvent in a single reaction vessel (“one-pot”). The organic polymer can be patterned prior to mixing the organic polymer with the nanomaterial. In some embodiments, the reducible material can be decorated with nanostructures. In embodiments, when the organic polymer is BOPP, the polymer can be treated with flame or corona plasma discharge. In a non-limiting embodiment, the organic polymer and nanomaterial are mixed in the absence of solvent. A suitable solvent can include water, alcohols, ethanol, glycol, tetrahydrofuran (THF), dimethyl sulfoxide (DMSO) or mixtures thereof. In some embodiments, the reducing agent is the solvent, for example, the organic polymer and the nanomaterial are mixed in hydrazine monohydrate. The mixture can be heated to a temperature suitable to allow the reducing agent to react with the organic polymer and the nanomaterial. The temperature can be from 25 to 500° C., 50 to 250° C., or 75 to 100° C., or the refluxing temperature of the solvent.

1. Deposition of the Reducible Nanomaterial on the Surface of a Polymer

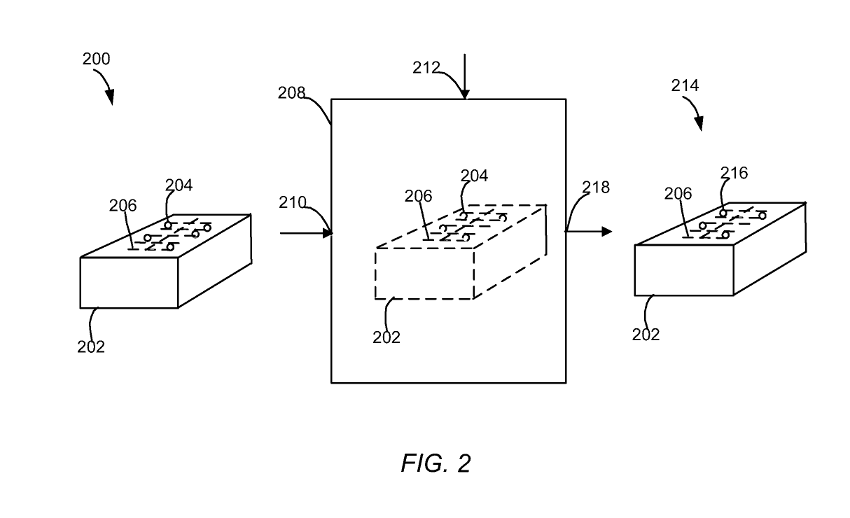

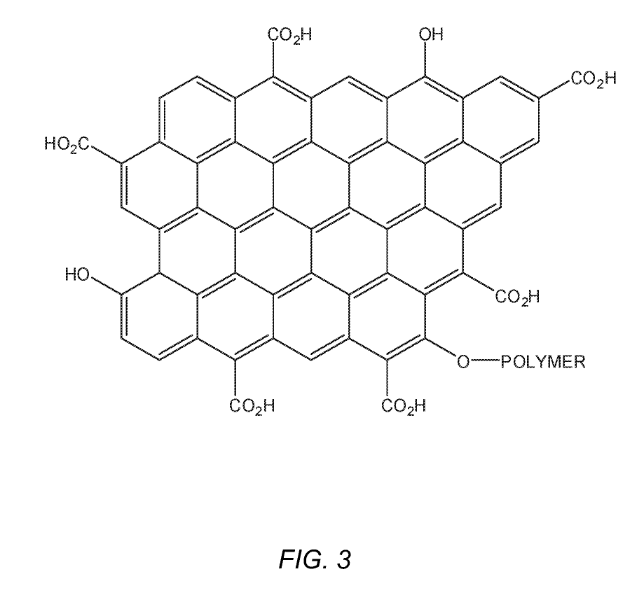

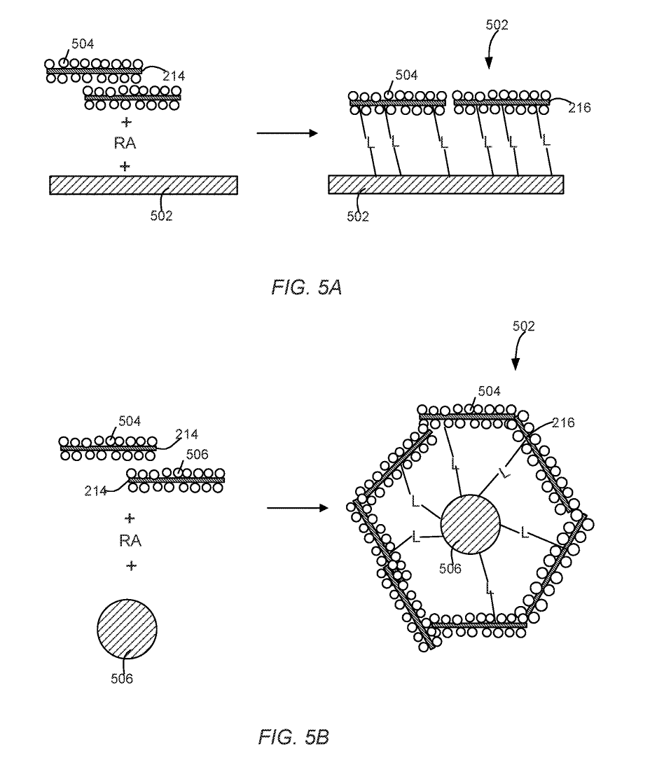

FIG. 2 is a schematic of a method for forming the polymer material of the present invention. The reducible nanomaterial 202 can be deposited on the surface of polymer 204. The reducible nanomaterial 202 can include nanostructures deposited on the surface (see, FIG. 5). The deposition can be done through chemical vapor deposition, transfer tape, roll-to-roll, or any other known deposition method. In some embodiments, the organic polymer, for example, BOPP, nanomaterial, and reducing agent are subject to a plasma discharge under a reducing agent atmosphere. As shown in FIG. 2, organic polymer 202 includes reducible nanomaterial (“nanomaterials”) 204. As shown in FIG. 2, the reducible nanomaterials 204 are positioned in grooves 206 that have been patterned on the surface of the polymer 202. The polymer 202 with deposited reducible nanomaterials 204 can enter the reaction unit 208 via inlet 210. The polymer 202 with deposited reducible nanomaterials can be obtained from a third party or the deposition can occur offsite or in another unit of a manufacturing facility. The reducing agent can enter reaction unit 208 through inlet 212. In some embodiments, the reducing agent can be put in the reaction unit 208 and the polymer 202 with deposited reducible nanomaterials 204 can then be added to the reaction unit 208. The polymer 202 with deposited reducible nanomaterials 204 can be heated in the presence of the reducing agent until the reducible nanomaterial is reduced and the polymeric material 214 having reduced nanoparticles 216 is formed. In some instances, a majority or substantially all of the reduced nanomaterials 216 are attached to the surface of polymer 202. The polymeric material 214 can exit the reaction unit 208 via polymeric outlet 218. FIG. 3 is a contemplated structure of the polymeric material 214 when the reduced nanomaterial is reduced graphene oxide. As shown in FIG. 3, an oxygen atom of the reduced graphene oxygen is bonded to the polymer. The amount of reduction can be controlled by reaction time and/or the amount of reducing agent. In one embodiment, the reducing agent is applied to the surface of the polymer and then the reducible nanomaterials are deposited on the surface of the polymer. Upon heating the organic polymer 206, reducible nanomaterials 204, and reducing agent in the reaction unit 208, the reducing agent, organic polymer, and reducible nanomaterials react such that the reducible nanomaterial attaches or covalently bonds to the organic polymer.

2. Spray Coating of Reducible Nanomaterial

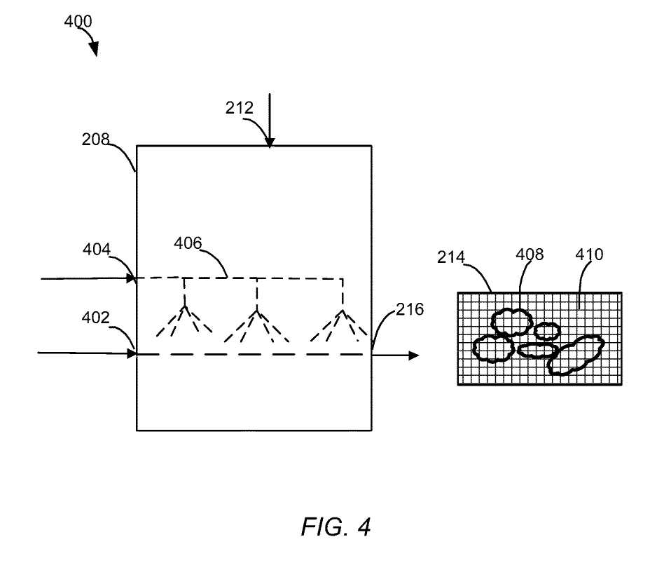

FIG. 4 is a schematic of a method for forming the polymer material of the present invention. An organic polymer stream can enter the reaction unit 208 via organic polymer stream inlet 402. A reducible nanomaterial stream (e.g., an aqueous solution of the reducible nanomaterials such as, for example, graphene oxide colloids, or graphene oxide flakes) can enter the reaction unit via reducible nanomaterial stream inlet 404 and be deposited on the organic polymer 206. As shown in FIG. 4, the reducible nanomaterials are being applied using spray device 406. In some embodiments, the organic polymer and the reducible nanomaterials enter the reaction unit 208 in one stream or the two streams can be combined prior to enter the reaction unit. The reducing agent (e.g., an aqueous stream reducing agent such as, for example, hydrazine hydrate) can enter reaction unit 208 through reducing inlet 212. In some embodiments, the reducing agent can be put in the reaction unit 208 and prior to the polymer stream and reducible nanomaterial entering the reaction unit 208. In some embodiments, the reducing agent is applied to the organic polymer followed by a coating of the reducible material (with or without deposited nanostructures). The polymer 206 with deposited reducible nanomaterials 204 can be heated in the presence of the reducing agent until the reducible nanomaterial is reduced and the polymeric material 214 having reduced nanoparticles 216 is formed. In some instances, substantially all of the reduced nanomaterials 216 are attached to the surface of polymer 206. The polymeric material 214 can exit the reaction unit 208 via polymeric material outlet 218. In a particular embodiment, reaction unit 208 is plasmatron and the polymer 206 and reducible nanomaterial 204 are subject to plasma radiation under a reducing agent atmosphere while in the plasmatron. In some embodiments, the polymer is a mesh, a sheet, a film, or a bead. As shown in FIG. 4, polymeric material 214 includes reduced nanomaterial (e.g., graphene flakes) 408 attached or linked to the polymeric mesh 410.

3. Reducible Nanomaterial With Deposited Nanostructures on the Surface of a Polymer

In some instances, the polymeric material can be made by coating a polymeric substrate with a reducing agent and the reducible nanomaterials with deposited nanostructures. The coating of the reducing agent and/or reducible nanomaterials as described above in Section B(2) or using other known coating methods (e.g., dip coating). FIGS. 5A and 5B depict a schematic of method 500 to prepare the polymeric material that includes reducible material decorated with the nanostructures. Referring to FIG. 5A a polymeric sheet or film 502 can be coated with an aqueous solution reducing agent RA (e.g., hydrazine (NH₂NH₂)) and then coated with an aqueous reducible nanomaterial 214 deposited with nanostructures 504. Referring to FIG. 5B a polymeric bead 506 can be coated with a reducing agent RA (e.g., hydrazine (NH₂NH₂)) and then coated with a reducible nanomaterial 214 deposited with nanostructures 504. In some embodiments, the polymeric bead 506 can include nano- or microparticles (e.g., metal oxides) or polymer brush architectures. The coated polymeric sheet, film or bead can be heated to about 75° C. to 85° C. until the reaction between the polymer, reducible nanomaterial and the reducing agent is complete (e.g., 8 to 12 hours). The reducing agent reacts with the reducible material and the polymer and forms linker (L), which links or attaches the polymer material (e.g., polymeric film/sheet 502 or polymeric bead 506) to the reduced material 216. For example, hydrazine NH₂NH₂ can react with the carboxylic acid of graphene oxide and a carboxylic acid functional group of a polymer to form an acylated hydrazide shown below.

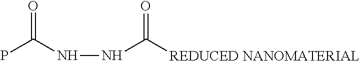

where P is the polymeric substrate

Without wishing to be bound by theory, it is believed that one or more pathways can produce the polymeric material. A first pathway can include stepwise reactions of the reducing agent with the organic polymer material and/or the nanomaterials to form intermediates that react to form the polymeric material. A first pathway can include the reducing agent reacting with the organic polymer to form a polymer-reducing agent intermediate. The polymer reducing agent intermediate can react with the reducible nanomaterial and form the polymeric material 214. A second pathway can include the reducing agent reacting with the nanomaterial to form a reducible nanomaterial-reducing agent intermediate. The reducible nanomaterial-reducing agent intermediate can react with the polymer to form the polymeric material 214. A third pathway can include the formation of the two intermediates which then react or form the polymeric material 214.

The reducible nanomaterial can undergo 1 to 100%, 10%, 20%, 50%, 75%, 80%, 90%, or 100% reduction. In some embodiments, the reduced nanomaterial includes a mixture of reduced and unreduced sites, however, the amount of reduction of the nanomaterial is sufficient to allow attachment of the reduced nanomaterial to the surface of the polymer. A ratio of reduced and unreduced sites in the reduced nanomaterial 216 can range from 0.0001:100 to 1:99, or 10:90, 20:80, or 50:50. In a non-limiting example, polymeric material 214 includes reduced graphene oxide as the reduced nanomaterial. The reduced graphene oxide can have a mixture of reduced and unreduced sites.

The nanocomposites of such polymer structures with graphene, or graphene heterostructures, wrapped around the polymer can be treated to remove the encapsulated polymer (e.g., heat treated in an oxidizing atmosphere) to result in hollow graphene-based architectures. This approach provides a significantly less complicated method for hollow graphene architectures preparation as compared to conventional methods, which typically require multiple templating and acid/base etching steps. Such architectures will be useful for catalysis, sensors, plasmonics, electrodes, and energy storage.

### C. Uses of the Produced Polymeric Material

The produced polymeric materials of the present invention can be used in a wide range of applications and electronic devices.

By way of example, the process of the present invention can be used to create either or both of the upper and lower electrodes for a single device or can be used to create cathodes and anodes for a single device. By way of example only, the materials of the present invention can be incorporated into a wide variety of devices, including any device that currently makes use of transparent conductors (such as metal oxide films) or reflective conductors or both. For instance, the following devices are contemplated: (i) Electronic display devices including an electroluminescent (EL) device (e.g., an organic light emitting display (OLED)), an electrophoretic display (e-paper), an electrochromic device, a liquid crystal display device (e.g., transflective liquid crystal display (LCD) devices) or an electrowetting display device; (ii) Photovoltaic cells, for instance amorphous silicon (a-Si) cells; (iii) Light irradiation devices and decorative illumination devices, for instance, devices containing light-emitting elements such as light-emitting diodes and semiconductor lasers; (iv) Electromagnetic radiation shield devices; (v) Any device which requires a reflective electrode; and (vi) Electronic device e.g., a transistor, a resistor, a logic device, sensors, antennas, integrated circuits, electroluminescence devices, memory elements or a field effect device.

In some embodiments, the polymeric material can be a fiber mesh integrated with graphene. The reducing agent (e.g., hydrazine) based one-step treatment can be utilized to coat graphene and link the flakes to the surface of fibers, bridge fibers, and uniformly disperse and integrate flakes within the fiber mesh. This method can overcome problems associated with high temperature in-situ growth of graphene using copper-coated mesh structures. Apart from that, the physically-mixed graphene flakes (in fiber mesh) due to less z-direction strength impart low shear strength to such composites. This shear strength can be significantly improved by utilizing the methods as described in this application. Being a single-step and water-based functionalization process, the challenges of multi-step and non-specific functionalization approaches can be overcome. For example, polymer fiber mesh integrated with reduced graphene oxide made using the methods described herein can be useful for optical fiber protection coatings, functional coatings, masking for printed electronics, lightening protection system, smart textile, sensors, and high-strength and light-weight structural material. Coatings can include optical fiber protection coatings, functional coatings, and masks for printed electronics. Functional coating can include coatings with a capability to send chemical and biological agents, humidity, brine, stress; gas barrier coatings and thermally or electronically conductive coatings.

In other aspects of the invention, the polymeric material of the present invention can be used as a pollution control and mitigation platform by catalyzing the destruction of undesired gases such as SOx and NOx. In some aspects of the invention, the polymeric material is used in a gas separation surface where two gases can be separated based on differential absorption rate to the surface.

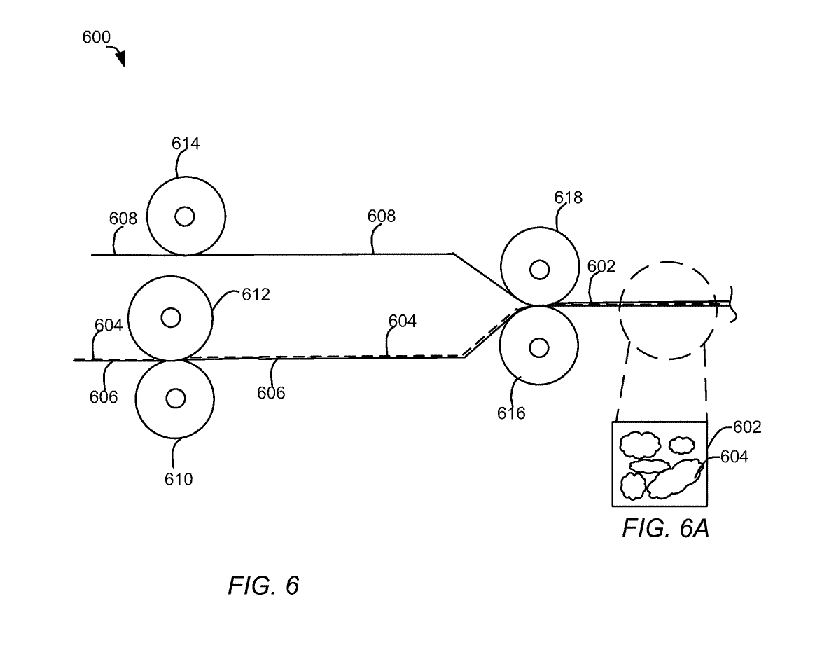

The polymeric material can be used in a roll-to roll process to produce polymer sheets, membranes, films or the like. FIG. 6 depicts a schematic of a roll-to roll process 600 to make a flexible nano-laminate 602 that includes reduced nanomaterial 604 (e.g., reduced graphene). In this approach, a first rolled sheet of polymeric material 606 containing the reduced nanomaterial 604 can be rolled in conjunction with second rolled sheet of incoming polymeric material 608 using rollers 610, 612 and 614. As the two sheets 606 and 608 merge, they can be hot-pressed or fused to result in a flexible nano-laminate 602 using rollers 616 and 618 with uniformly-dispersed reduced nanomaterial 604 in the middle of fused sheets 606 and 608. FIG. 6A is a top view of the laminate with the top sheet 608 removed. The second rolled polymeric material can include the same or different polymers than the first rolled sheet. In some embodiments, the second rolled polymeric material can include a same or different reduced nanomaterial than the first rolled polymeric material. Such polymer nanocomposites or nano-laminates are advantageous for applications where anisotropic properties are desired. These properties could be thermal, mechanical, electrical, and optical. Such flexible nano-laminates or nanocomposite films could be utilized for paper or flexible electronics.

### EXAMPLES

The present invention will be described in greater detail by way of prophetic examples. The following examples are offered for illustrative purposes only, and are not intended to limit the invention in any manner. Those of skill in the art will readily recognize a variety of noncritical parameters which can be changed or modified to yield essentially the same results.

### Example 1

### Synthesis of Polymeric Material with Reduced Graphene

Graphene oxide nanocolloids (2 mg of graphene oxide nanocolloids/1 mL of water) were purchased from Sigma-Aldrich® (USA). Hydrazine hydrate (55% diluted) was purchased from Acros Organics (USA), and PET was bought in the form of transparency slides. A slide of PET was cleaned with water and dried. The dried sheet was coated with a diluted hydrazine hydrate (1 ml, 60 mM of hydrazine in water) at room temperature to produce a hydrazine coated PET substrate. The hydrazine coated PET substrate was further coated with a drop of the aqueous graphene oxide nanocolloid solution (2 mg/ml). The hydrazine/graphene oxide coated PET substrate was dried in an oven at 80° C. for overnight. The samples were characterized by Fourier Transform Infrared (FTIR) spectroscopy and optical microscopy. The procedure was repeated 3 times to produce 3 samples. FTIR was conducted on the 3 different samples and for each sample more than 5 points were generated for analysis.

### Example 2: Comparative Example

### PET with Hydrazine

In order to evaluate the deoxygenation or reduction of graphene oxide during the process of coating on PET substrate, a comparative experiment was conducted. A slide of PET was cleaned with water and dried. The dried sheet was coated with a diluted hydrazine hydrate (1 ml, 60 mM of hydrazine in water) at room temperature to produce a hydrazine coated PET substrate. The hydrazine coated PET substrate was dried in an oven at 80° C. for overnight. The samples were characterized by Fourier Transform Infrared (FTIR) spectroscopy and optical microscopy.

### Example 3

### FTIR Interpretation

Table 1 lists the FTIR peaks of: a untreated PET slide, standard PET stretches, Comparative Example 1 (hydrazine-treated PET) stretches, standard terathalic dihydrazide stretches, Example 1 (PET with reduced graphene oxide), standard graphene oxide stretches, standard reduce graphene oxide stretches, and standard hydrazine hydrated stretches.

TABLE 1

| | | | | | | | Std hydrazine |
|---|---|---|---|---|---|---|---|
| | Std PET | Comparative | Std terathalic | | Std GO | Std rGO | hydrated |
| PET Blank | stretches¹ | Example 1 | dihydrazide² | Example 2 | stretches³ | stretches³ | and stretches⁴ |
| 2953.37 cm⁻¹, | 3100-2800 | 3315 (N—H, | 3327, 3213, | 3428.92 | 3400 (O—H | 3400 (O—H | 3340 |
| 2050.90 | (aromatic | primary | 3071, 3061, | (shifted due | stretch) | stretch), | |
| (stretching | and aliphatic | amides) | 3050, 3036 | to mix of N—H | | significantly | |
| mode of | —C—H) | | | and O—H | | suppressed | |
| aliphatic —CH2— | | | | stretch) | | due to | |
| in ethylene | | | | | | deoxygenation | |
| glycol | | | | | | of GO | |
| segment in | | | | | | | |
| amorphous | | | | | | | |
| regions, | | | | | | | |
| changes with | | | | | | | |
| crystallinity) | | | | | | | |
| 1979.99 (too | Doublet at | 1490 (aromatic | 1629, 1616, | 2952.33, | 1720 (C═O | 1720 (C═O | 1613 |
| weak, | 2960 and | ring) | 1608, 1544, | 2883.55 (CH₂ | stretch) | stretch) | |
| possible | 2910 | | 1492, 1343, | and CH | | | |
| contaminant) | (stretching | | 1292, 1246, | vibrations⁵ | | | |
| | mode of | | 1240, 1187, | associated to | | | |
| | aliphatic | | 1143, 1106, | remaining | | | |
| | —CH2— | | 1017 | COOH | | | |
| | in ethylene | | | groups in GO) | | | |
| | glycol | | | and overlap with | | | |
| | segment in | | | stretching | | | |
| | amorphous | | | mode of | | | |
| | regions, | | | aliphatic —CH2— | | | |
| | changes with | | | in ethylene | | | |
| | crystallinity) | | | glycol | | | |
| | | | | segment in | | | |
| | | | | amorphous | | | |
| | | | | regions, | | | |
| | | | | changes with | | | |
| | | | | crystallinity) | | | |
| 1713.14 (ester | 1720 (ester | 1340 (C—N) | 930, 889, 882, | 2324.41, | 1600 | | 1461 |
| C═O, depends | C═O) | | 738, 714, 641, | 2160.71, | (skeletal | | |
| on | | | 631, 503, 497, | 2139.64, | vibrations | | |
| crystallinity) | | | | 2050.84, | from | | |
| | | | | 1979.33 | unoxidized | | |
| | | | | (weak, | graphitic | | |
| | | | | possible | domains) | | |
| | | | | contaminant, | | | |
| | | | | also observed | | | |
| | | | | in blank PET) | | | |
| 1578.82, | 1300 (ester | 1628 (C═O) | | 1711.65 | 1220 (C—OH | | 1360 |
| 1504.42 | group) | | | (C═O stretch, | stretching) | | |
| (crystallinity | | | | shifted from | | | |
| extent) | | | | blank PET). | | | |
| | | | | This shift | | | |
| | | | | could be | | | |
| | | | | attributed to | | | |
| | | | | amide 1 and | | | |
| | | | | amide 2 | | | |
| | | | | bands. | | | |
| 1470.41 | 1100 | 1290 (N—N) | | 1578.61, | 1060 (C—O | 1060 (C—O | 1285 |
| (crystallinity | (methylene) | | | 1505.18 (due | stretching) | stretching, | |
| extent, trans | | | | to PET, | | remaining | |
| form of | | | | shifted from | | carboxyl | |
| ethylene | | | | blank PET, | | groups) | |
| glycol | | | | both peaks | | | |
| segment) | | | | become | | | |
| | | | | stronger). | | | |
| | | | | This could | | | |
| | | | | attributed to | | | |
| | | | | N—H stretch | | | |
| | | | | due to amide | | | |
| | | | | bonds or | | | |
| | | | | secondary | | | |
| | | | | amide | | | |
| | | | | groups)⁶ | | | |
| 1453.06 (cis | 1470, 1340, | | | 1470.46 (due | | | 1074 |
| form of | 975, 845 - | | | to PET) | | | |
| ethylene | transform of | | | | | | |
| glycol | ethylene | | | | | | |
| segment | glycol | | | | | | |
| 1409.16, | segment | | | | | | |
| 1340.71 | 1450, 1370, | | | 1453.64 (due | | | 894 |
| (crystallinity | 1040, 898 - | | | to PET) | | | |
| extent and | cis for of | | | | | | |
| influence on | ethylene | | | | | | |
| resonance on | glycol | | | | | | |
| the | segment | | | | | | |
| teraphthalate | | | | | | | |
| group, in- | | | | | | | |
| plane | | | | | | | |
| alignment of | | | | | | | |
| carbonyl | | | | | | | |
| groups with | | | | | | | |
| benzene ring | | | | | | | |
| 1241.28 | 1042 (anti- | | | 1408.99 | | | 427 |
| (stretching | symmetrical | | | (This peak is | | | |
| vibrations of | C—O stretch | | | shifted from | | | |
| ester groups, | of cis form | | | blank PET | | | |
| —C—O—C═O) | | | | and could be | | | |
| | | | | attributed to | | | |
| | | | | C—N stretch | | | |
| | | | | in amide | | | |
| | | | | bonds) | | | |
| 1096.80 (ester | | | | 1341.73 (due | | | |
| C—O—C bond, | | | | to PET) | | | |
| cis isomer of | | | | | | | |
| ethylene | | | | | | | |
| glycol | | | | | | | |
| segment) | | | | | | | |
| 1017.21 (in- | | | | 1240.90 (due | | | |
| plane bending | | | | to PET) | | | |
| of the C—H | | | | | | | |
| bonds of a | | | | | | | |
| 1,4-di-substrituted | | | | | | | |
| aromatic ring | | | | | | | |
| 969.16, | | | | 1096.94 (due | | | |
| 871.57, | | | | to PET) | | | |
| 846.60, | | | | | | | |
| 792.45 | | | | | | | |
| (conformation | | | | | | | |
| of ethylene | | | | | | | |
| glycol unit) | | | | | | | |
| 722.80, | | | | 1045.55 (C—O | | | |
| 631.61, | | | | stretching) | | | |
| 601.65 (out | | | | | | | |
| of plane | | | | | | | |
| bending of C—H, | | | | | | | |
| in-plane | | | | | | | |
| bending of | | | | | | | |
| C-bonds of | | | | | | | |
| benzene ring) | | | | | | | |
| 530.66, | | | | 1017.17, | | | |
| 505.53, | | | | 969.47, | | | |
| 435.24 (could | | | | 871.55, | | | |
| be attributed | | | | 846.09, | | | |
| to teraphthalic | | | | 792.58, | | | |
| dihydrazide | | | | 722.75, | | | |
| and remaining | | | | 631.66, | | | |
| hydrazine | | | | 601.68, | | | |
| hydrate) | | | | 530.06, | | | |
| | | | | 506.1, 437.59 | | | |
| | | | | (could be | | | |
| | | | | attributed to | | | |
| | | | | PET, | | | |
| | | | | teaphthalic | | | |
| | | | | hydrazide, and | | | |
| | | | | hydrazine | | | |
| | | | | hydrate) | | | |

¹Chen et al., European Polymer Journal, 2012, 48, 1586-1610.
²Soni et al., Journal of Applied Polymer Science, 2009, 113, 1090-1096.
³Choi et al., Journal of Materials Chemistry, 2010, 20, 1907-1912.
⁴http://www.hanhonggroup.com/ir/ir_en/RB01060076.html
⁵Basirun et al., Nanoscale Research Letters, 2013; 8, 397.
⁶Tripathi et al., Synthesis of High-Quality Graphene through Electrochemical Exfoliation of Graphite in Alkaline Electrolyte, arXiv: 1310.7371

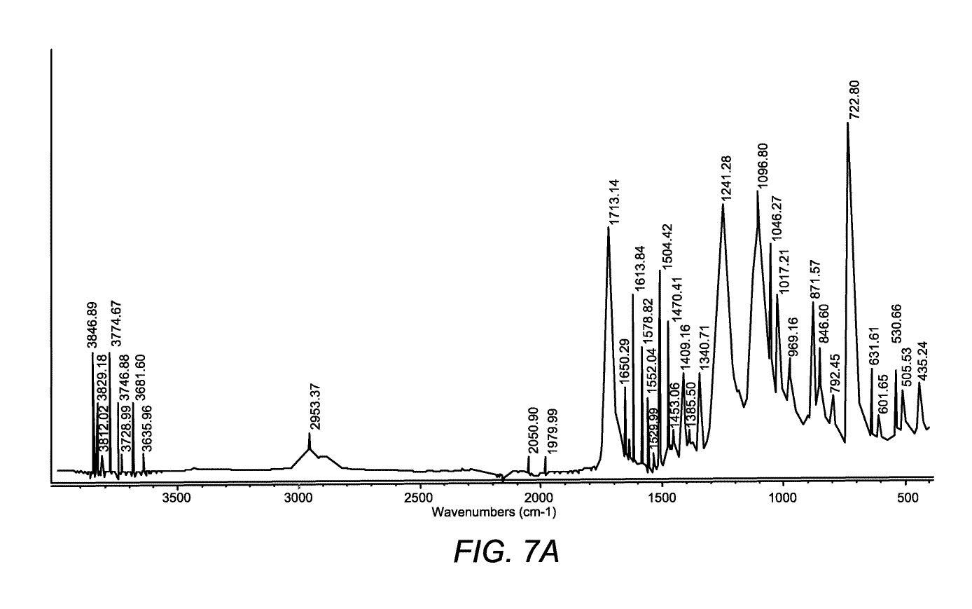

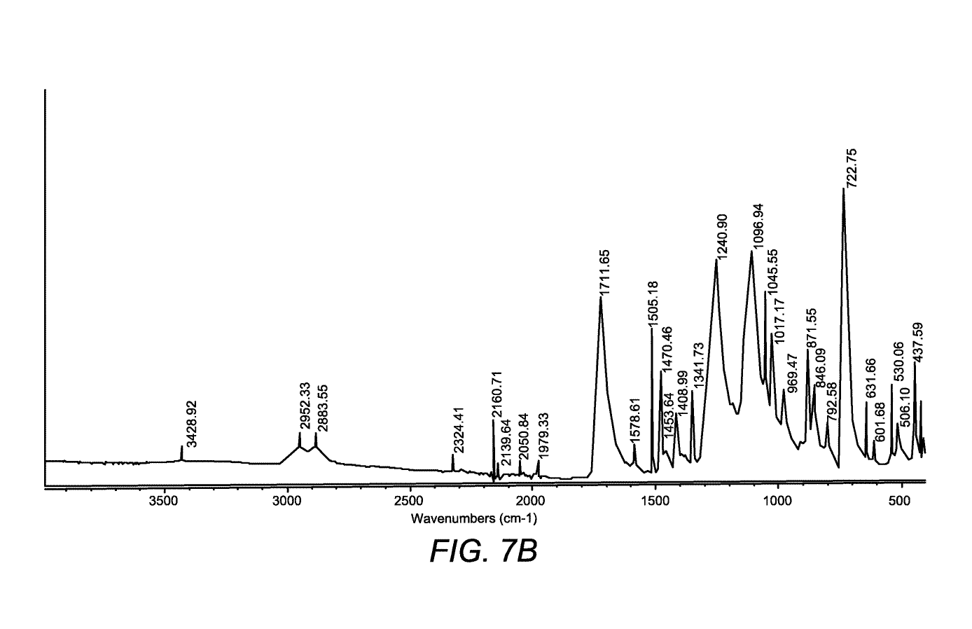

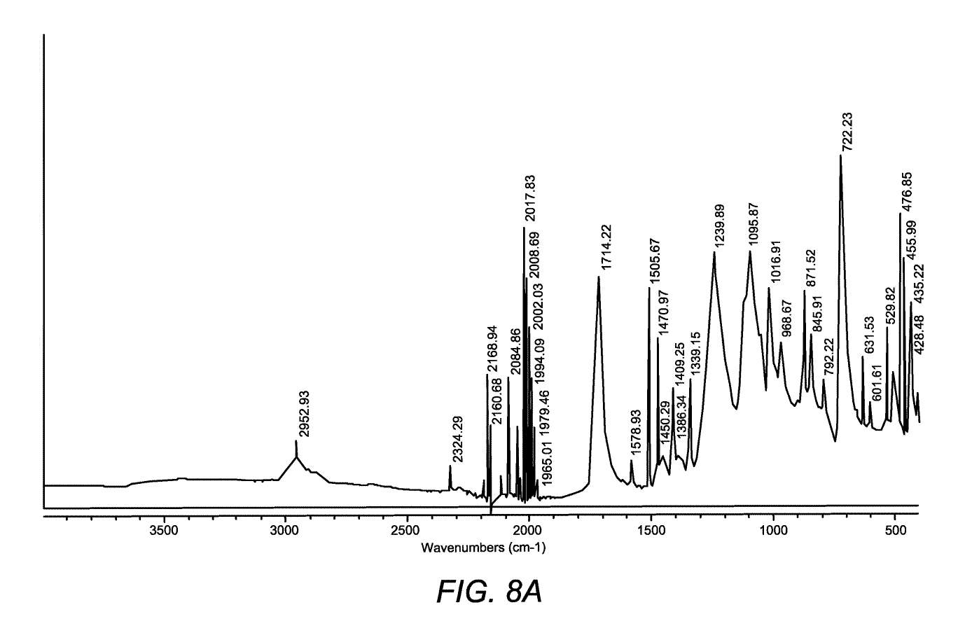

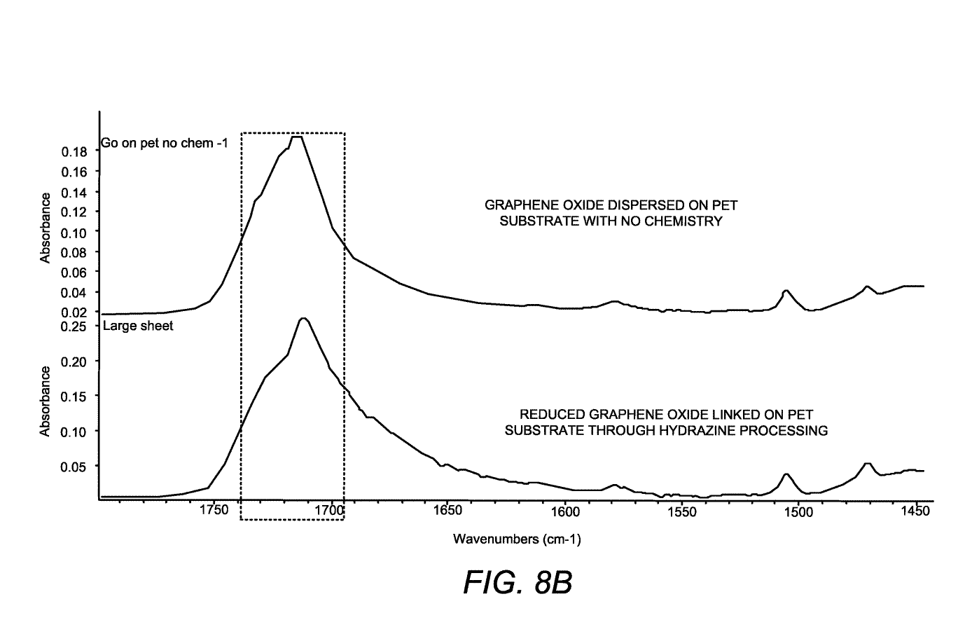

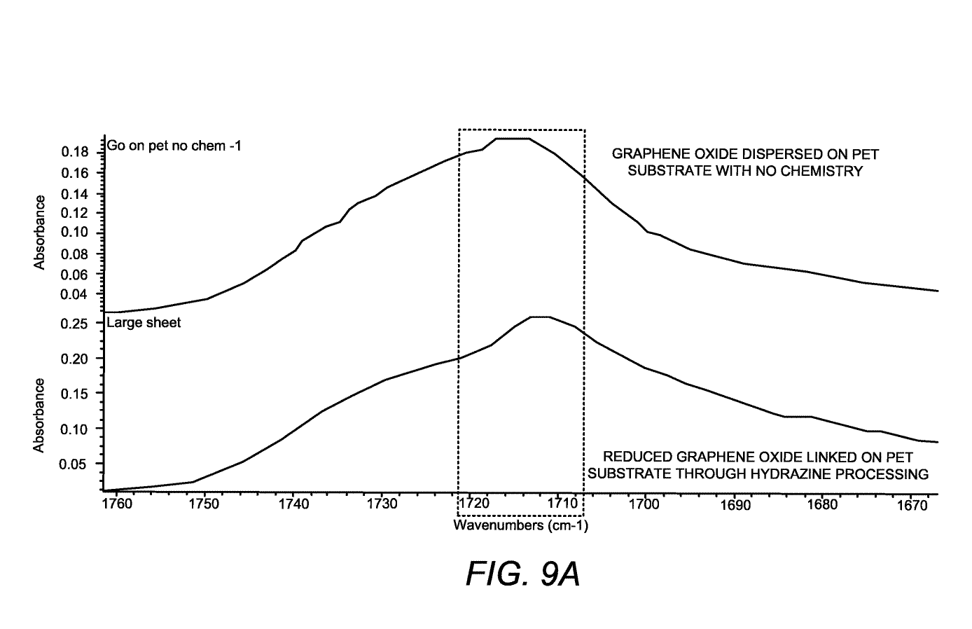

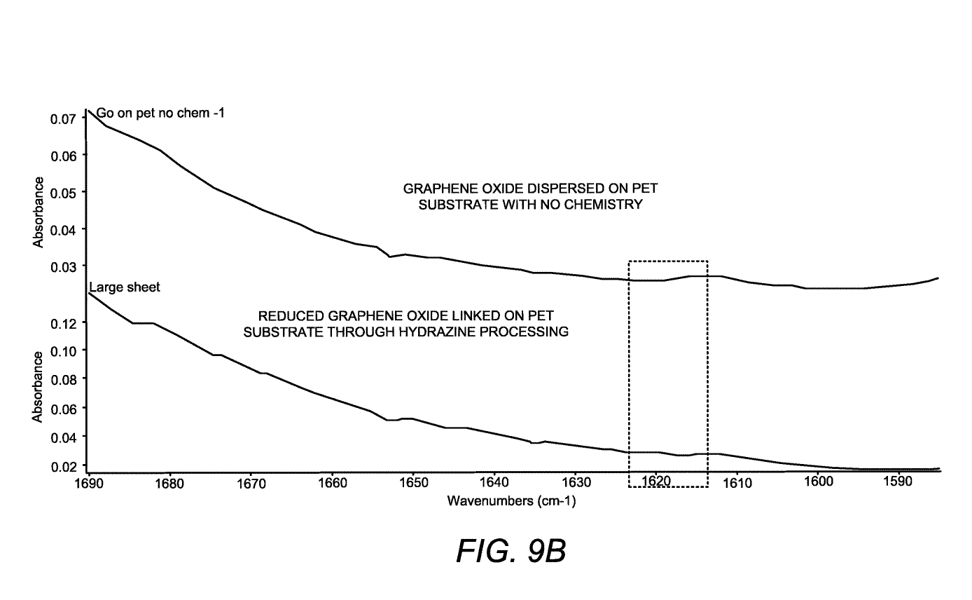

FIG. 7A shows an FTIR spectrum for a blank and FIG. 7B shows an FTIR spectrum for a coated PET substrate. FIG. 8A shows the FTIR spectra for graphene oxide dispersed on PET with no chemistry. FIG. 8B shows the comparison of the carbonyl stretch region for FIG. 8A and FIG. 7B. The dotted rectangle indicates the compared region. FIG. 9A is an enlarged region of the FIG. 8B FTIR spectra. FIG. 9B is an enlargement of the carbonyl stretch region (around 1620 cm⁻¹) for graphene oxide dispersed on PET substrate with no chemistry (top spectra) and hydrazine processed coating of the present invention (Example 1 sample, bottom spectra) of the FIG. 8B FTIR spectra. The dotted rectangle indicates the compared regions. Many of the similarities in the spectra of graphene coated PET and the blank PET could be attributed to the PET substrate and contaminants as indicated in the Table 1 (above). Specific FTIR peaks are attributed to hydrazine-based linkage of reduced graphene oxide nanoplatelets to the PET substrate in a single-step approach. The peak at 3428.92 cm⁻¹, which was absent in the blank PET, was attributed to a mix of O—H and N—H stretches due to hydrazine attachment on the PET substrate. The peak at 1711.65 cm⁻¹ was attributed to C═O stretch. This peak was shifted from blank PET stretch at 1713.14 cm⁻¹ due to ester C═O stretch and also depended on polymer crystallinity. This shift was attributed to amide 1 and amide 2 bands formation on the PET substrate when integrated with the graphene oxide nanoplatelets. Other C═O and C—H stretches corresponding to carboxylic groups (—COOH) were observed as listed in Table 1 (above). Although the samples were washed with copious amounts of water after the binding process, the presence of some of carboxylic or oxygenated groups could be due to unbound graphene oxide on PET substrate. The peaks centered around 1578.61 cm⁻¹ and 1505.18 cm⁻¹ were shifted from that of blank PET sample. This shift was attributed to N—H stretch due to amide bonds or secondary amide groups formed during the binding process. Finally, the peak centered around 1408.99 cm⁻¹ (shifted from blank PET) and was attributed to C—N stretch in amide bonds.

It was observed that a twin peak present in graphene oxide (˜1710 cm⁻¹, FIGS. 8B and 9A) converted to single peak. This was a clear indication of loss of C═O groups, which further attested to the formation of reduced graphene oxide during the integration with PET in presence of hydrazine. In addition, the focus was on the region (1500-1700 cm⁻¹) for carbonyl stretches. This region has been critical for identifying C═O stretches in carbon nanotubes (See, Majumder et al., “Effect of tip functionalization on transport through vertically oriented carbon nanotube membranes.” Journal of the American Chemical Society, 2005, Vol. 127, pp. 9062-9070 and Chopra et al., “Bifunctional carbon nanotubes by sidewall protection.” Advanced Functional Materials, 2005, Vol. 15, pp. 858-864). Disappearance of the shoulder around 1620 cm⁻¹ (FIG. 9B) is another indication of loss of C═O groups and formation of reduced graphene oxide on PET in presence of hydrazine.

### Example 4

### Optical Microscopy Interpretation

A clear or semi-transparent coating on the surface of PET of Example 1 was observed under 500× magnification optical microscope.

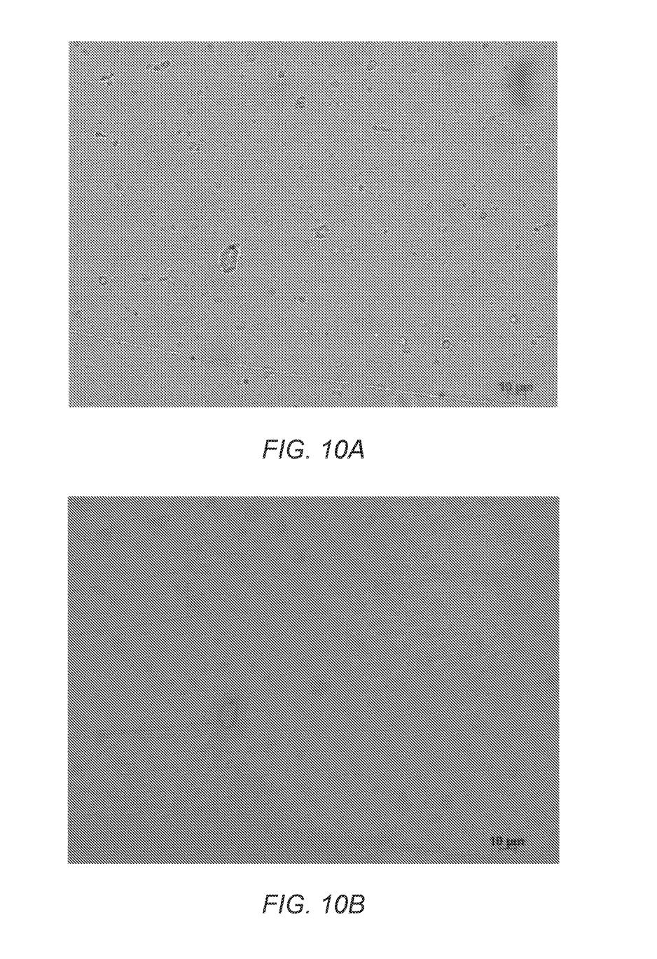

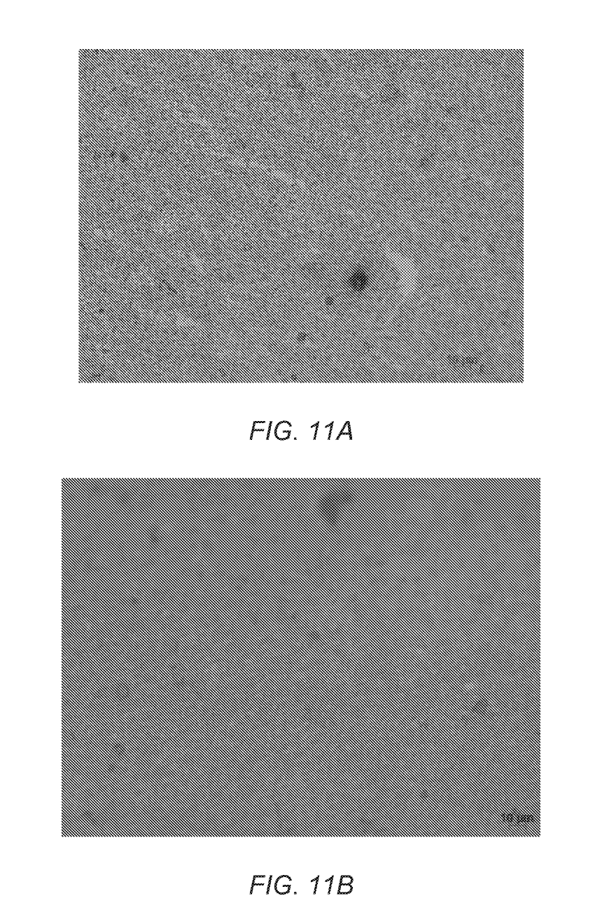

FIGS. 10A and 10B are blank PET substrate (10A: transmission mode optical image; 10B: reflection mode optical image). FIGS. 11A and 11B are PET substrate uniformly coated with graphene nanoplatelets (11A: transmission mode optical image; 11B: reflection mode optical image). The scale bar for all images was 10 μm for all the images. FIGS. 10 A and 10B shows blank PET with defects or contaminants. The PET substrate with the reduced graphene coating was difficult to scratch with a sharp razor and it was determined to be strongly bound to the PET substrate.

### Example 5

### Peel Test

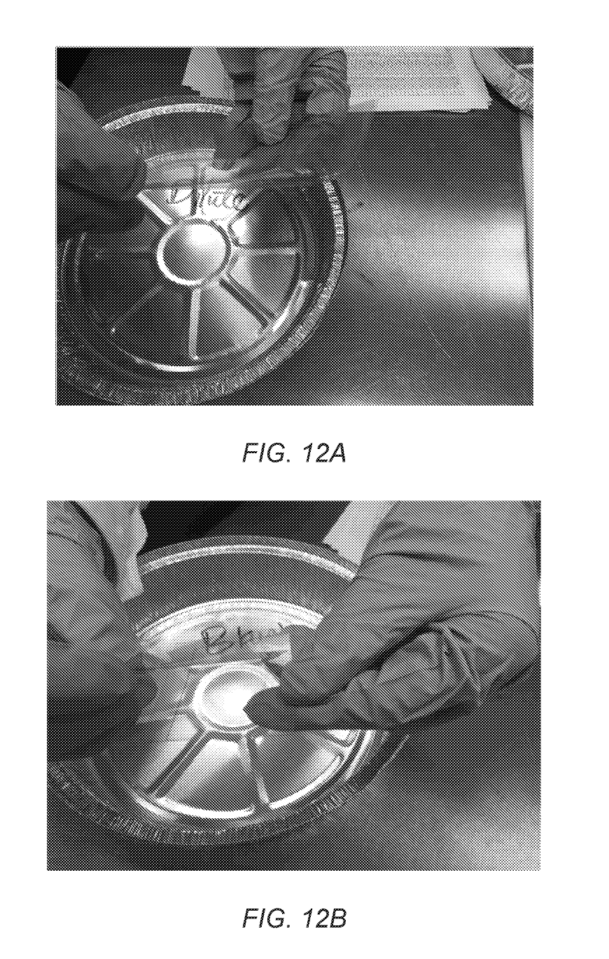

Two blank PET sheets were coated with 1 ml of 60 mM hydrazine hydrate. 0.01 wt % graphene oxide was coated on one of the hydrazine-coated PET sheet. The second hydrazine-coated PET sheet was flipped on top of first sheet (with hydrazine and graphene oxide). The sandwiched samples were dried for 24 hours at 80° C. A control PET-graphene oxide-PET sandwich sample was prepared, but without any hydrazine. The dried samples were manually peeled. The sandwich sample with hydrazine treatment (FIG. 12A) was significantly difficult to peel while the control sample (FIG. 2B) did not stick and the two PET sheets were easily separated on drying.

### Example 5

### Scanning Electron Microscopy

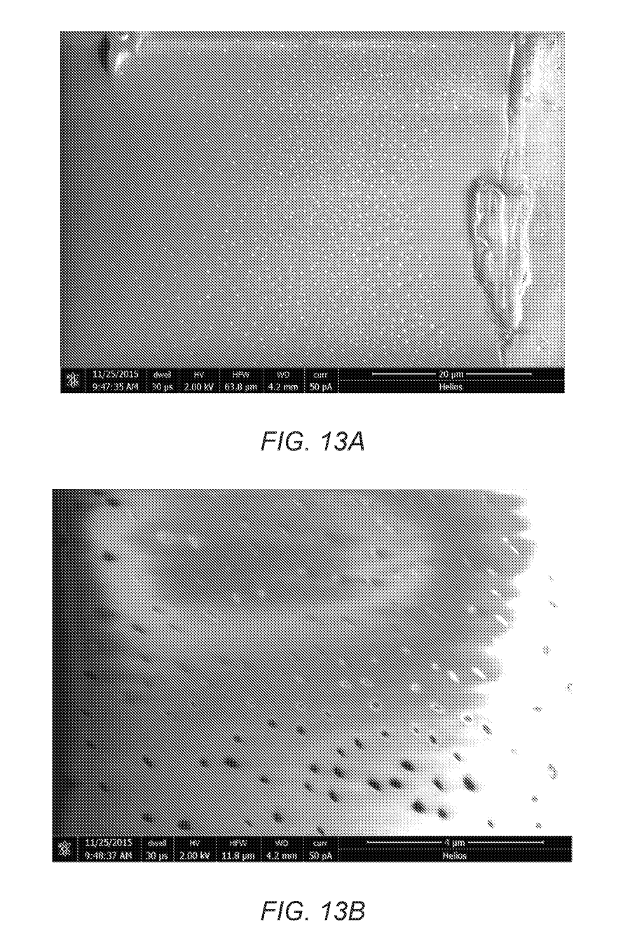

A small (0.5 cm×0.5 cm) sample from Example 1 was placed on the SEM stub and inserted in the microscope for analysis. Reduced GO nanoplatelets can be seen as dots in the SEM images. FIGS. 13A and 13B are scanning electron microscope (SEM) images of PET uniformly coated with reduced graphene oxide (or graphene) nanoplatelets at a 20 μm and 4 μm scale respectively.

As shown in the Examples, the methods of the present invention resulted in reduced graphene oxide strongly attached (bonded) to the surface of PET. The experiments with graphene sandwiched between two PET sheets also resulted in strong binding between the sheets.

1. A method for attaching a reducible nanomaterial to an organic polymer, the method comprising subjecting a reaction mixture comprising the reducible nanomaterial and the organic polymer to a reducing agent under reaction conditions sufficient to reduce the nanomaterial, activate the organic polymer, and attach the reduced nanomaterial to the organic polymer during the reaction.

2. The method of claim 1, further comprising obtaining the reaction mixture by depositing the reducible nanomaterial on the organic polymer.

3. The method of claim 2, wherein the reaction mixture is treated with the reducing agent after the reducible nanomaterial has been deposited on the organic polymer or during deposition of the reducible nanomaterial on the organic polymer.

4. The method of claim 1, wherein the reducible nanomaterial is an oxygen-containing carbon nanostructure, a defect-containing carbon nanotube, a transition metal compound, or a transition metal oxide.

5. The method of claim 4, wherein the reducible nanomaterial comprises additional nanostructures, wherein the nanostructures and/or additional nanostructures are nanorods, nanowires, nanoparticles, quantum dots, or any combination thereof.

6. The method of claim 5, wherein the additional nanostructures comprise a metal oxide, a metal, a bi-metallic compound, a tri-metallic compound, an alloy, a carbon-based compound, a carbide, a chalcogenide, or any combination thereof.

7. The method of claim 4, wherein the oxygen-containing carbon nanostructure is graphene oxide.

8. The method of claim 4, wherein the transition metal compound or the transition metal oxide comprises vanadium.

9. The method of claim 1, wherein the organic polymer is a thermoplastic polymer or blend thereof.

10. The method of claim 1, wherein the reducing agent is a nitrogen containing compound, wherein the nitrogen containing compound comprises is a mono-amine, a di-amine, a polyamine, a hydrazine, a hydrazine monohydrate, a di-imide, or mixtures thereof.

11. The method of claim 1, wherein the nanomaterial has not previously been reduced or activated.

12. The method of claim 1, wherein the organic polymer is in the form of an organic polymeric substrate and the reduced nanomaterial is attached to the surface of the substrate after the reaction.

13. The method of claim 12, wherein the substrate is in the form of a film, sheet, or a fiber mesh.

14. The method of claim 1, wherein the reduced nanomaterial is covalently attached to the organic polymer or the reduced material is attached to the organic polymer via hydrogen bonds or via a combination of hydrogen bonds and covalent bonds after the reaction.

15. The method of claim 1, wherein the reaction mixture is an aqueous mixture.

16. A polymeric material having reduced graphene oxide attached to the surface of an organic polymer, wherein the polymeric material is prepared by the process of claim 1.

17. The polymeric material of claim 16, wherein the polymeric material is comprised in an electronic device.

18. The polymeric material of claim 16, wherein the polymeric material is an electrode.

19. The polymeric material of claim 18, wherein the electrode is in a capacitor.

20-25. (canceled)

26. The method of claim 1, wherein the reducing agent is hydrazine monohydrate.
